(19) United States
(12) Patent Application Publication
(10) Pub. No.: US 2023/0253232 A1
(43) Pub. Date: Aug. 10, 2023

(54) SUBSTRATE TREATMENT APPARATUS

(71) Applicant: ASM IP Holding B.V., Almere (NL)

(72) Inventor: Naoto Tsuji, Tokyo (JP)

(21) Appl. No.: 18/106,635

(22) Filed: Feb. 7, 2023

Related U.S. Application Data
(60) Provisional application No. 63/308,861, filed on Feb. 10, 2022.

(51) Int. Cl. H01L 21/683; H01J 37/32; C23C 16/509; C23C 16/46; C23C 16/458; C23C 16/455

(52) U.S. Cl. CPC H01L 21/6833; H01J 37/32568; H01J 37/3255; H01J 37/32165; H01J 37/32724; C23C 16/509; C23C 16/46; C23C 16/4586; C23C 16/45536; H01J 2237/2007; H01J 2237/332

(57) ABSTRACT

[Problem] A substrate treatment apparatus that can protect an AC power supply connected to a heater is provided.

[Means for solving the problem] A substrate treatment apparatus includes a lower electrode formed of a dielectric, a first AC power supply that is connected to a first internal electrode included in the lower electrode and supplies AC power with a first frequency, a heater included in the lower electrode to heat the lower electrode, a filter circuit connected to the heater, and a second AC power supply connected to the heater via the filter circuit and used for the heater, in which the filter circuit includes a parallel circuit that connects a low-pass filter with a cut-off frequency that is lower than the first frequency and a high-pass filter with a cut-off frequency that is higher than the first frequency in parallel.

### CROSS-REFERENCE TO RELATED APPLICATIONS

This application claims priority to U.S. Provisional Patent Application Ser. No. 63/308,861 filed Feb. 10, 2022 titled SUBSTRATE TREATMENT APPARATUS, the disclosure of which is hereby incorporated by reference in its entirety.

### BACKGROUND

### Technical Field of the Invention

The present disclosure relates to a substrate treatment apparatus used for substrate treatment such as film formation.

### Related Art

Patent Document 1 discloses a film forming apparatus with a plasma treatment reaction chamber.

[Patent Document 1] Japanese Unexamined Patent Application, First Publication No. 2018-93179

### SUMMARY

### Disclosure of the Invention

Problems to be Solved by the Invention

There is a substrate treatment apparatus for treating a substrate on a lower electrode by supplying AC power to the lower electrode while supplying a material gas to the gap between the lower electrode and an upper electrode to generate plasma between the lower electrode and the upper electrode. An AC power supply that applies a current to a heater is needed to heat the substrate on the lower electrode in such a substrate treatment apparatus. However, there is a problem that the AC power supply connected to the heater is damaged due to the AC power supplied to generate plasma.

The present disclosure has been achieved taking the above-described circumstance into consideration and aims to provide a substrate treatment apparatus that can protect an AC power supply connected to a heater.

Means for Solving the Problem

A substrate treatment apparatus according to the invention of the present application includes a lower electrode formed of a dielectric, a first AC power supply that is connected to the lower electrode and supplies AC power with a first frequency, a heater included in the lower electrode to heat the lower electrode, a filter circuit connected to the heater, and a second AC power supply connected to the heater via the filter circuit and used for the heater, in which the filter circuit includes a parallel circuit that connects a low-pass filter with a cut-off frequency that is lower than the first frequency and a high-pass filter with a cut-off frequency that is higher than the first frequency in parallel.

Effects of the Invention

According to the present disclosure, a low-pass filter with high impedance against AC power with a first frequency and a high-pass filter with high impedance against AC power with the first frequency are connected in parallel. As a result, the AC power supply for the heater can be protected from the AC power.

### BRIEF DESCRIPTION OF THE DRAWINGS

FIG. 1 is a cross-sectional diagram of a substrate treatment apparatus according to a first embodiment.

FIG. 2 is a circuit diagram of a filter circuit according to the first embodiment.

FIG. 3 is a diagram illustrating an operation of the substrate treatment apparatus.

FIG. 4 is a cross-sectional diagram of a substrate treatment apparatus according to a second embodiment.

FIG. 5 is a circuit diagram of a filter circuit according to the second embodiment.

FIG. 6 is a cross-sectional diagram of a substrate treatment apparatus according to a third embodiment.

FIG. 7 is a circuit diagram of a filter circuit according to the third embodiment.

FIG. 8 is a cross-sectional diagram of a substrate treatment apparatus according to a fourth embodiment.

FIG. 9 is a circuit diagram of a filter circuit according to the fourth embodiment.

FIG. 10 is a graph showing frequency characteristics of a low-pass filter circuit according to the fourth embodiment.

FIG. 11 is a graph showing frequency characteristics of a high-pass filter circuit according to the fourth embodiment.

### DETAILED DESCRIPTION

### Embodiments of the Invention

First embodiment

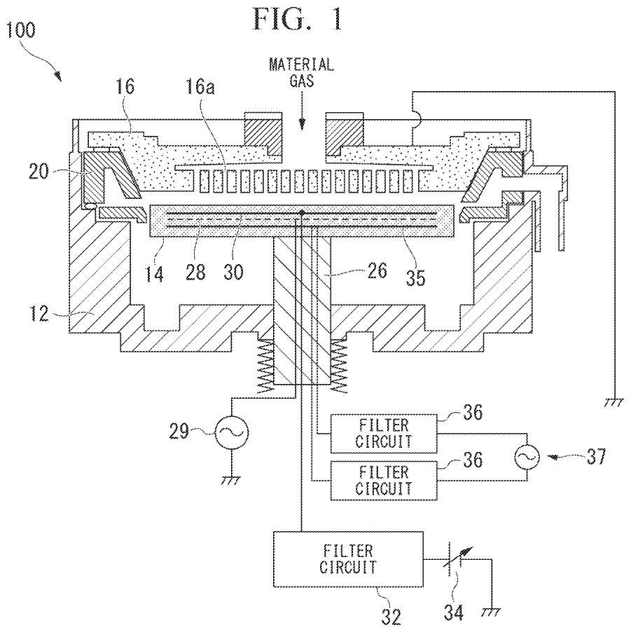

A substrate treatment apparatus according to a first embodiment of the present disclosure will be described below with reference to the drawings. FIG. 1 is a cross-sectional diagram of a substrate treatment apparatus 100 according to the first embodiment. The substrate treatment apparatus 100 includes a chamber 12. The chamber 12 includes a lower electrode 14 formed of a dielectric and an upper electrode 16 disposed to face the lower electrode 14. A material of the lower electrode 14 is, for example, a ceramic such as AlN. The upper electrode 16 includes slits 16a. A material gas is supplied to the gap between the lower electrode 14 and the upper electrode through the slits 16a.

An exhaust duct 20 is fixed to the chamber 12 and the upper electrode 16 via an O-ring. The exhaust duct surrounds the space between the upper electrode 16 and the lower electrode 14. The gas supplied to the gap between the upper electrode 16 and the lower electrode 14 to be used for substrate treatment is discharged to the outside through the exhaust duct 20.

The upper electrode 16 is connected to the ground.

The lower electrode 14 is supported by the supporting part 26. The lower electrode 14 and the supporting part 26 are integrated to form a susceptor. The lower electrode 14 is also called an RF electrode.

The lower electrode 14 includes a first internal electrode 28. The first internal electrode 28 is connected to a first AC power supply 29. A material of the first internal electrode 28 is a high melting-point metal, for example, tungsten, tantalum, molybdenum, niobium, ruthenium, hafnium, or the like. A shape of the first internal electrode 28 may be a metal mesh shape or a punched metal shape. The first AC power supply 29 supplies AC power with a first frequency. The first frequency can be, for example, a frequency in a range from 10 to 300 MHz, and a frequency equal to or higher than 30 MHz is called a very high frequency (VHF). The first AC power supply 29 of the first embodiment supplies, for example, AC power of 60 MHz.

The lower electrode 14 includes a heater 35 to heat the lower electrode 14. The heater 35 is provided in, for example, a spiral shape in a plan view. The heater 35 is connected to a filter circuit 36 by wiring passing through the supporting part 26. A second AC power supply 37 used for the heater 35 is connected to the heater 35 via the filter circuit 36. When the second AC power supply 37 supplies a current to the heater 35, the lower electrode 14 is heated and a substrate on the lower electrode 14 is heated as well. The second AC power supply 37 applies, for example, AC power with a frequency of 50 or 60 Hz.

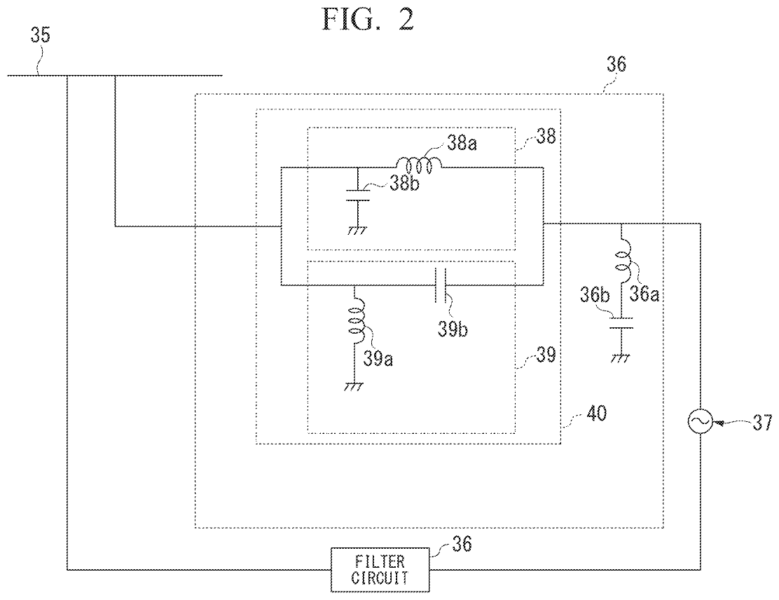

FIG. 2 is a circuit diagram of the filter circuit 36. In FIG. 2, two filter circuits 36 are shown. Two filer circuits 36 are the same. The filter circuit 36 includes a parallel circuit 40, an inductor 36a, and a capacitor 36b. In the parallel circuit 40, a low-pass filter 38 with high impedance against AC power with the first frequency is connected in parallel to a high-pass filter 39 with high impedance against AC power with the first frequency. The inductor 36a and the capacitor 36b serve as a series circuit to connect the parallel circuit 40 to the ground. The inductor 36a and the capacitor 36b are provided to allow only AC power of the second AC power supply 37 to pass therethrough and remove a higher frequency than that of the AC power. The inductor 36a and the capacitor 36b may not be provided because they are not essential constituent components.

The low-pass filter 38 includes an inductor 38a and a capacitor 38b. The capacitor 38b is provided between the heater 35 and the ground. The inductor 38a is provided between the heater 35 and the second AC power supply 37. In addition, the inductor 38a is provided on wiring branching from the wiring connecting the heater 35 and the capacitor 38b. The low-pass filter 38 has high impedance against the first frequency. In other words, the low-pass filter 38 has a function of cutting off AC power with the first frequency. In a case in which the first frequency is 60 MHz, the capacitor 38b is set to 0.9 nF, and the inductor 38a is set to 2.25 pH, for example, the cut-off frequency of the low-pass filter 38 is 5 MHz, the gain is −40 dB, and thus the low-pass filter 38 has high impedance against the first frequency. The cut-off frequency of the low-pass filter 38 (which may be referred to as a “first cut-off frequency”) is lower than the first frequency.

The high-pass filter 39 includes an inductor 39a and a capacitor 39b. The inductor 39a is provided between the heater 35 and the ground. The capacitor 39b is provided between the heater 35 and the second AC power supply 37. In addition, the capacitor 39b is provided on wiring branching from the wiring connecting the heater 35 and the inductor 39a. The high-pass filter 39 has high impedance against the first frequency. The high-pass filter 39 has a function of cutting off AC power with the first frequency. In a case in which the first frequency is set to 60 MHz, the inductor 39a is set to 28 fF, and the capacitor 39b is set to 70 pH, for example, the cut-off frequency of the high-pass filter 39 (which may be referred to as a “second cut-off filter”) is 80 GHz, the gain is −40 dB, and thus the high-pass filter 39 has high impedance against the first frequency. The cut-off frequency of the high-pass filter 39 (which may be referred to as a “second cut-off frequency”) is higher than the first frequency.

The low-pass filter 38 attenuates the components of a higher frequency than the first cut-off frequency so that AC power with the first frequency is attenuated. In addition, the high-pass filter 39 attenuates the components of a lower frequency than the second cut-off frequency so that AC power with the first frequency is attenuated. The first frequency is between the first cut-off frequency and the second cut-off frequency. By setting the first cut-off frequency and the second cut-off frequency as described above, the blocking frequency can be widened.

The lower electrode 14 includes a second internal electrode 30. The second internal electrode 30 is, for example, a metal formed in a mesh shape in a plan view. A material of the second internal electrode 30 may be, for example, tungsten (W). The second internal electrode 30 is connected to a filter circuit 32 by wiring passing through the supporting part 26. The second internal electrode 30 and a DC power supply 34 are connected via the filter circuit 32. The DC power supply 34 applies a voltage to the second internal electrode 30 to provide an electrostatic chuck.

The filter circuit 32 has high impedance against AC power with the first frequency. A circuit diagram of the filter circuit 32 may have a similar configuration to the filter circuit 36. The filter circuit 32 is an example of a third filter circuit connected to the second internal electrode 30.

### Operation of Substrate Treatment Apparatus

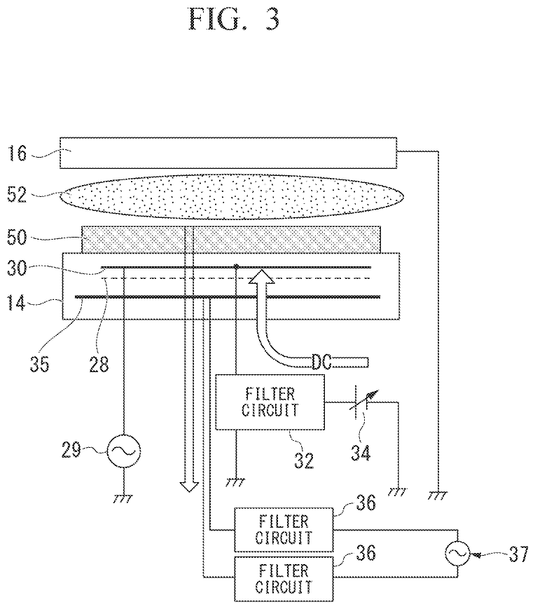

An operation of the substrate treatment apparatus during substrate treatment will be described. FIG. 3 is a diagram showing a simplified configuration of FIG. 1 to describe the operation performed during substrate treatment for easier understanding. Substrate treatment starts with a substrate 50 disposed on the lower electrode 14. The substrate 50 may be, for example, a Si wafer. The temperature of the Si wafer is raised to a predetermined temperature by the heater 35. AC power with the first frequency is supplied to the lower electrode 14 from the first AC power supply 29 while supplying a material gas to the gap between the upper electrode 16 and the lower electrode 14. Plasma 52 is generated in the gap between the upper electrode 16 and the lower electrode 14 by applying the AC power with the first frequency to the lower electrode 14. When a voltage is applied to the second internal electrode 30 by the DC power supply 34 in that state, the lower electrode 14 is polarized, which electrostatically attracts the substrate 50 to the lower electrode 14. As a result, an electrostatic chuck can be provided.

In a case in which a frequency is changed to perform matching adjustment in a filter circuit of the related art, for example, AC power cannot be sufficiently attenuated at the time of generation of plasma, the AC power with the first frequency flows to the power supply system side of the heater 35, and thus there is concern that the power supply system of the heater 35 and further the entire apparatus cannot be protected from RF noise.

The substrate treatment apparatus 100 according to the first embodiment can be given a wider range of blocking frequency by connecting the low-pass filter 38 and the high-pass filter 39 in parallel to each other. As a result, AC power can be prevented from flowing to the heater 35.

Although the low-pass filter 38 is constituted by the inductor and the capacitor in the first embodiment, it is not limited to a particular filter as long as it is a circuit having a cut-off frequency that is lower than the first frequency. Although the high-pass filter 39 is constituted by the inductor and the capacitor, it is not limited to a particular filter as long as it is a circuit having a cut-off frequency that is higher than the first frequency. Treatment details of the substrate treatment apparatus according to the first embodiment are not limited to particular ones as long as they involve plasma treatment. The substrate treatment apparatus may be used as a plasma-enhanced atomic layer deposition (PEALD) device or a plasma-enhanced chemical vapor deposition (PECVD) device. The filter circuit of the heater in the present embodiment may be used as a filter circuit of an electrostatic chuck.

### Second Embodiment

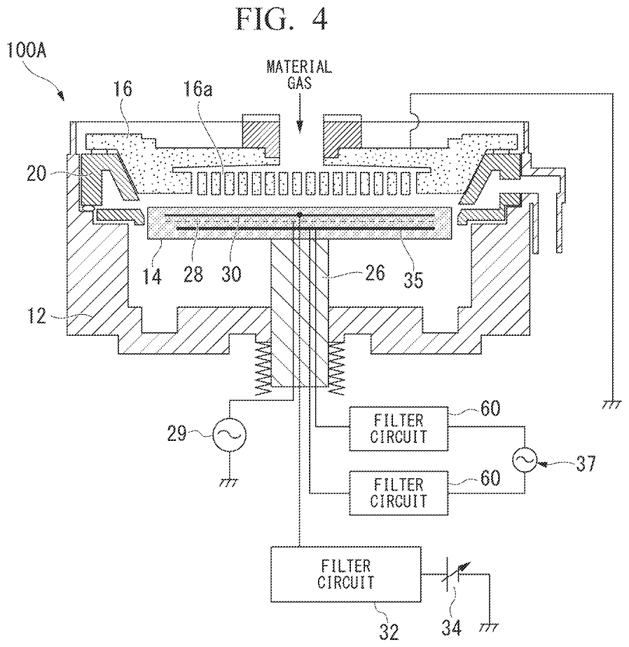

Next, a substrate treatment apparatus 100A of a second embodiment according to the present disclosure will be described with reference to FIG. 4. Further, in the second embodiment, the same reference numerals are given to the same constituent components as those in the first embodiment, and description thereof may be omitted.

FIG. 4 is a cross-sectional diagram of the substrate treatment apparatus 100A. The substrate treatment apparatus 100A includes a filter circuit 60 instead of the filter circuit 36.

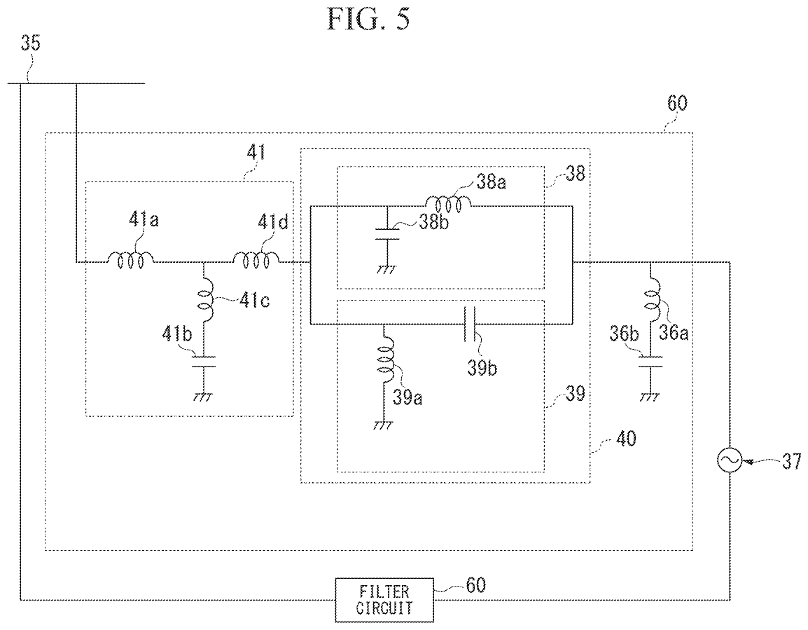

FIG. 5 is a circuit diagram of the filter circuit 60. In FIG. 5, two filter circuits 60 are shown. Two filer circuits 60 are the same. The filter circuit 60 includes a second low-pass filter 41, a parallel circuit 40, an inductor 36a, and a capacitor 36b. In the parallel circuit 40, a low-pass filter 38 with a cut-off frequency that is lower than the first frequency and a high-pass filter 39 with a cut-off frequency that is higher than the first frequency are connected in parallel. The inductor 36a and the capacitor 36b serve as a series circuit to connect the parallel circuit 40 to the ground.

The filter circuit 60 includes the second low-pass filter 41 between the heater 35 and the parallel circuit 40. The second low-pass filter 41 has high impedance against AC power with the first frequency. In other words, the cut-off frequency of the second low-pass filter 41 is lower than the first frequency.

The second low-pass filter 41 includes inductors 41a, 41c, and 41d and a capacitor 41b. The inductor 41a is provided between the heater 35 and the inductors 41c and 41d. The inductor 41c and the capacitor 41b serve as a series circuit to connect the inductor 41a to the ground. The inductor 41d is provided on wiring branching from the wiring connecting the inductors 41c and 41b. The inductor 41d is provided between the inductor 41a and the parallel circuit 40. In a case in which the first frequency is 60 MHz, the inductors 41a and 41d are set to 3.2 pH, the inductor 41c is set to 3.3 pH, and the capacitor 41b is set to 633 pF, for example, the cut-off frequency of the second low-pass filter 41 is 5 MHz, the gain is −60 dB, and thus the second low-pass filter 41 has high impedance against the first frequency.

The low-pass filter 38 includes an inductor 38a and a capacitor 38b. The capacitor 38b is provided between the heater 35 and the ground. The inductor 38a is provided between the heater 35 and the second AC power supply 37. In addition, the inductor 38a is provided on wiring branching from the wiring connecting the heater 35 and the capacitor 38b. The low-pass filter 38 has high impedance against the first frequency. In other words, the low-pass filter 38 has a function of cutting off AC power with the first frequency. The first cut-off frequency of the low-pass filter 38 is lower than the first frequency.

The high-pass filter 39 includes an inductor 39a and a capacitor 39b. The inductor 39a is provided between the heater 35 and the ground. The capacitor 39b is provided between the heater 35 and the second AC power supply 37. In addition, the capacitor 39b is provided on wiring branching from the wiring connecting the heater 35 and the inductor 39a. The high-pass filter 39 has high impedance against the first frequency. The high-pass filter 39 has a function of cutting off AC power with the first frequency. The second cut-off frequency of the high-pass filter 39 is higher than the first frequency.

The low-pass filter 38 attenuates the components of a frequency that is higher than the first cut-off frequency so that AC power with the first frequency is attenuated. In addition, the high-pass filter 39 attenuates the components of a frequency that is lower than the second cut-off frequency so that AC power with the first frequency is attenuated. The first frequency is between the first cut-off frequency and the second cut-off frequency. By setting the first cut-off frequency and the second cut-off frequency as described above, the blocking frequency can be widened.

The substrate treatment apparatus 100A according to the second embodiment can be given a wider range of the blocking frequency by connecting the low-pass filter 38 and the high-pass filter 39 in parallel. In addition, the substrate treatment apparatus 100A according to the second embodiment can attenuate AC power with the first frequency using the second low-pass filter 41. By inputting the AC power with the first frequency attenuated by the second low-pass filter 41 to the parallel circuit in which the low-pass filter 38 and the high-pass filter 39 are connected in parallel, the power supply system of the heater 35 and further the entire apparatus can be protected from RF noise.

Although the second low-pass filter 41 is constituted by the inductors and the capacitor, it is not limited to a particular filter as long as it is a circuit having a cut-off frequency lower than the first frequency.

### Third Embodiment

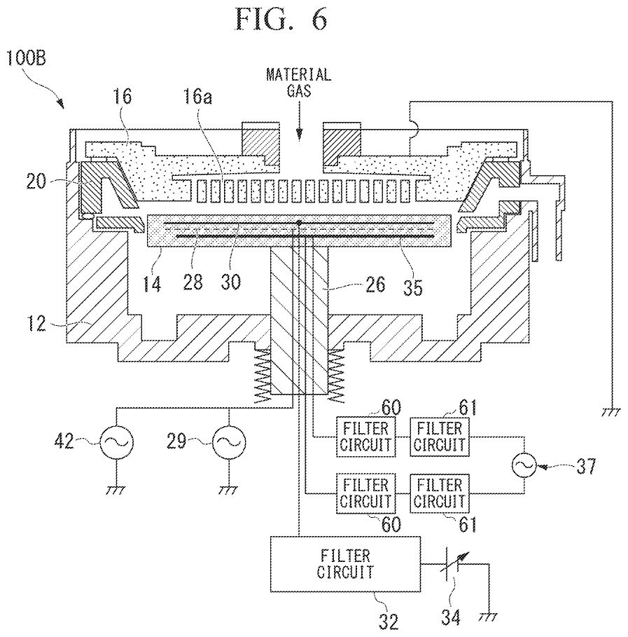

A substrate treatment apparatus 100B of a third embodiment will be described with reference to FIG. 6. Further, in the third embodiment, the same reference numerals are given to the same constituent components as those in the first and second embodiments, and a description thereof may be omitted.

FIG. 6 is a cross-sectional diagram of the substrate treatment apparatus 100B. The substrate treatment apparatus 100B includes a filter circuit 60 and a second filter circuit 61 instead of the filter circuit 36. In addition, the substrate treatment apparatus 100B includes a first AC power supply 29 that supplies AC power with the first frequency and a third AC power supply 42 that supplies AC power with the second frequency that is lower than the first frequency to the lower electrode 14.

A first internal electrode 28 is connected to the first AC power supply 29. The first AC power supply 29 supplies AC power with the first frequency. The first frequency can be, for example, a frequency in a range from 10 to 300 MHz. The first AC power supply 29 of the third embodiment supplies, for example, AC power of 60 MHz.

The first internal electrode 28 is connected to the third AC power supply 42. The third AC power supply 42 supplies AC power with the second frequency that is lower than the first frequency to the first internal electrode 28. The second frequency can be, for example, a frequency in a range from 100 kHz to 1000 kHz. A frequency in this frequency band is called a low radio frequency (LRF). The third AC power supply 42 supplies, for example, AC power of 430 kHz.

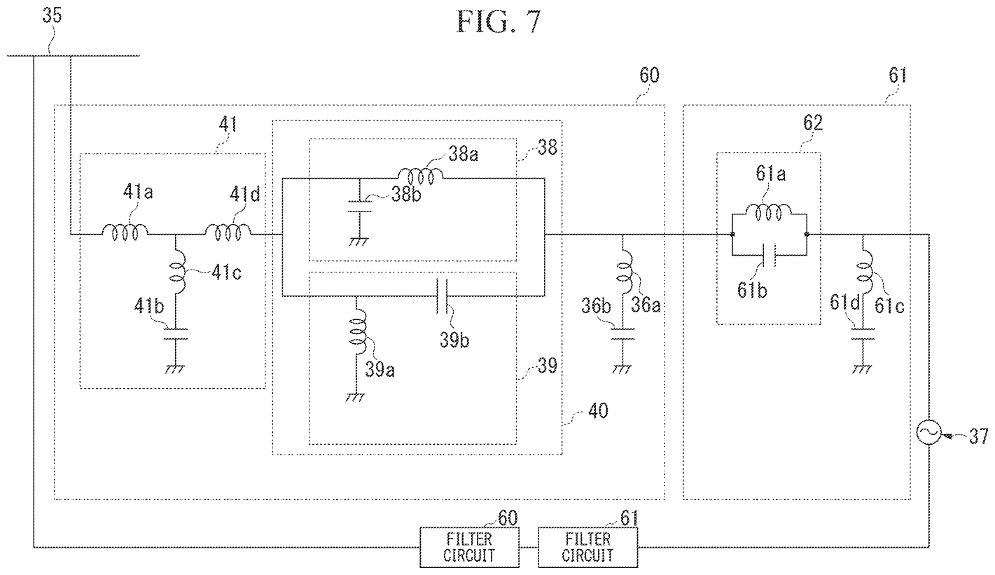

FIG. 7 is a circuit diagram of the filter circuit 60 and the second filter circuit 61. Two filter circuits 60 are shown in FIG. 7. Two filter circuits 60 are the same. Two second filter circuits 61 are shown in FIG. 7. Two second filter circuits 61 are the same. The filter circuit 60 and the second filter circuit 61 are provided between the heater 35 and the second AC power supply 37. The second filter circuit 61 is provided between the filter circuit 60 and the second AC power supply 37. The second filter circuit 61 has high impedance against AC power with the second frequency. In other words, the second filter circuit 61 attenuates AC power with the second frequency. For example, the second filter circuit 61 is a band-elimination filter that attenuates AC power with the second frequency.

The second filter circuit 61 includes an inductor 61a, a capacitor 61b, an inductor 61c, and a capacitor 61d. The inductor 61a and the capacitor 61b are connected in parallel. A circuit constituted by the inductor 61a and the capacitor 61b serves as a parallel circuit 62. The inductor 61c and the capacitor 61d serve as a series circuit to connect the parallel circuit 62 to the ground. The inductor 61c and the capacitor 61d are provided on wiring branching from the wiring connecting the parallel circuit 62 and the second AC power supply 37.

The substrate treatment apparatus 100B according to the third embodiment can be given a wider range of blocking frequency by connecting the low-pass filter 38 and the high-pass filter 39 in parallel. In addition, the substrate treatment apparatus 100B according to the third embodiment can attenuate AC power with the first frequency using the second low-pass filter 41. By inputting the AC power with the first frequency attenuated by the second low-pass filter 41 to the parallel circuit in which the low-pass filter 38 and high-pass filter 39 are connected in parallel, the power supply system of the heater 35 and further the entire apparatus can be protected from RF noise. The substrate treatment apparatus 100B according to the third embodiment can attenuate AC power with the second frequency using the second filter circuit 61. Thus, even when the third AC power supply that supplies AC power with a frequency lower than the first frequency is used together with the first AC power supply, the power supply system of the heater 35 and further the entire apparatus can be protected from RF noise.

Although the second filter circuit 61 is constituted by the inductors and the capacitors in the third embodiment, it is not limited to a particular filter circuit as long as it is a circuit having higher impedance against the second frequency.

### Fourth Embodiment

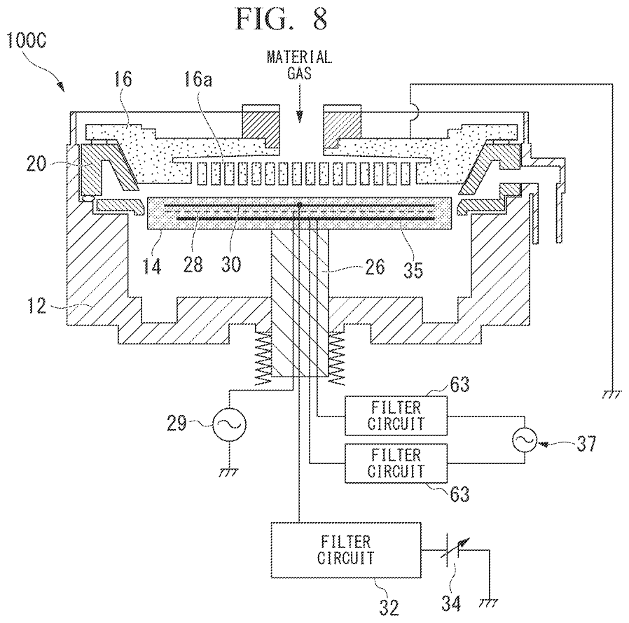

Next, a substrate treatment apparatus 100C of a fourth embodiment according to the present disclosure will be described with reference to FIG. 8. Further, in the fourth embodiment, the same reference numerals are given to the same constituent components as those in the first, second, and third embodiments, and a description thereof may be omitted.

FIG. 8 is a cross-sectional diagram of the substrate treatment apparatus 100C. The substrate treatment apparatus 100C includes a filter circuit 63 instead of the filter circuit 36.

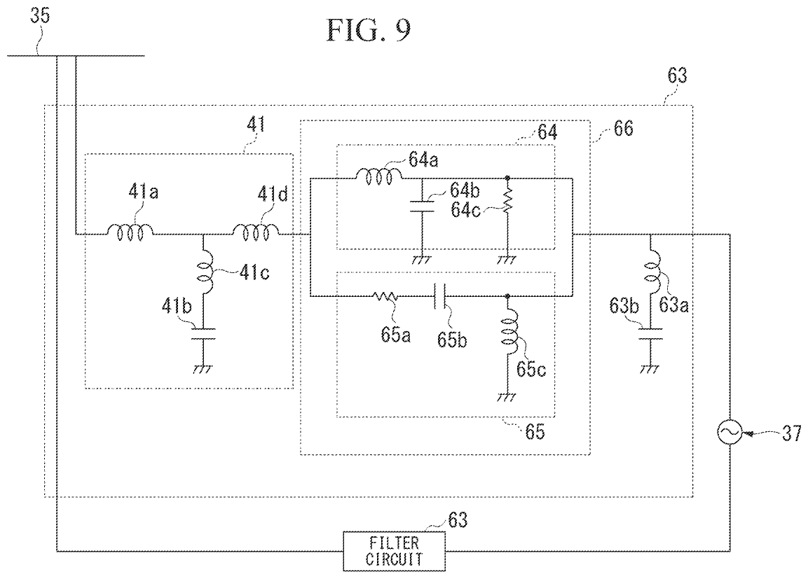

FIG. 9 is a circuit diagram of the filter circuit 63. Two filter circuits 63 are shown in FIG. 9. Two filter circuits 63 are the same. The filter circuit 63 includes a second low-pass filter 41, a parallel circuit 66, an inductor 63a, and a capacitor 63b. In the parallel circuit 66, a low-pass filter 64 having high impedance against AC power with the first frequency and a high-pass filter 65 having high impedance against AC power with the first frequency are connected in parallel. The parallel circuit 66 is provided between the second low-pass filter 41 and the second AC power supply. The inductor 63a and the capacitor 63b serve as a series circuit to connect the parallel circuit 66 to the ground.

The filter circuit 63 includes the second low-pass filter 41 between the heater 35 and the parallel circuit 66. The second low-pass filter 41 has high impedance against AC power with the first frequency.

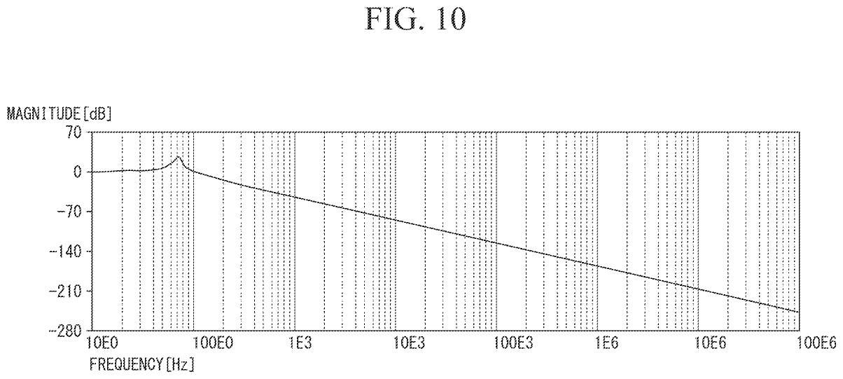

The low-pass filter 64 includes a resistor 64a, a capacitor 64b, and an inductor 64c. The capacitor 64b is provided between the resistor 64a and the ground. The inductor 64c is provided between the resistor 64a and the ground. The resistor 64a is provided between the second low-pass filter 41 and the second AC power supply 37. In addition, the capacitor 64b and the inductor 64c are provided on different lines of wiring, respectively, the wiring branching from the wiring connecting the second low-pass filter 41 and the second AC power supply 37. The low-pass filter 64 has high impedance against the first frequency. In other words, the low-pass filter 64 has a function of cutting off AC power with the first frequency. A case in which the resistor 64a is set to 1 MS2, the capacitor 64b is set to 500 g, and the inductor 64c is set to 10 mH can be considered, for example. Frequency characteristics of the low-pass filter 64 in this case are shown in FIG. 10. The vertical axis represents gain (dB), and the horizontal axis represents frequency (Hz). A first cut-off frequency is 150 Hz. When the first frequency is 60 MHz, the gain is −240 dB, and the low-pass filter 64 has high impedance.

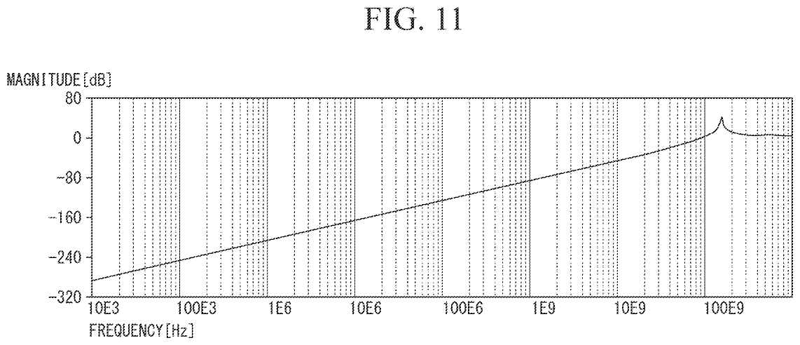

The high-pass filter 65 includes a resistor 65a, a capacitor 65b, and an inductor 65c. The capacitor 65b is provided between the resistor 65a and the second AC power supply 37. The inductor 65c is provided between the capacitor 65b and the ground. In addition, the inductor 65c is provided on wiring branching from the wiring connecting the capacitor 65b and the second AC power supply 37. The high-pass filter 65 has high impedance against the first frequency. The high-pass filter 65 has a function of cutting off AC power with the first frequency. A case in which the resistor 65a is set to 1 μΩ, the capacitor 65b is set to 1 pF, and the inductor 65c is set to 1 pH can be considered, for example. Frequency characteristics of the high-pass filter 65 in this case are shown in FIG. 11. The vertical axis represents gain (dB), and the horizontal axis represents frequency (Hz). The second cut-off frequency is 100 GHz. When the first frequency is 60 MHz, the gain is −140 dB, and the high-pass filter 65 has high impedance.

The low-pass filter 64 attenuates the components of a frequency that is higher than the first cut-off frequency so that AC power with the first frequency is attenuated. In addition, the high-pass filter 65 attenuates the components of a frequency that is lower than the second cut-off frequency. The first frequency is between the first cut-off frequency and the second cut-off frequency. By setting the first cut-off frequency and the second cut-off frequency as described above, the blocking frequency can be widened.

In addition, the substrate treatment apparatus 100C according to the fourth embodiment can attenuate AC power with the first frequency using the second low-pass filter 41. In addition, the range of the blocking frequency can be widened because the low-pass filter 64 and the high-pass filter 65 are included. Thus, the power supply system of the heater 35 and further the entire apparatus can be protected from RF noise.

Although the low-pass filter 64 is constituted by the resistor, inductor, and capacitor, it is not limited to a particular filter as long as it is a circuit having a cut-off frequency lower than the first frequency. Although the high-pass filter 65 is constituted by the resistor, inductor, and capacitor, it is not limited to a particular filter as long as it is a circuit having high impedance against the first frequency.

### Comparative Example

A comparative example in which a circuit configured for the frequency of 60 MHz is provided with the same configuration as the second filter circuit 61 instead of the filter circuit 60 can be considered with respect to the filter circuit 60 and the second filter circuit 61 of the third embodiment. Compared to the substrate treatment apparatus 100B of FIG. 6, a substrate treatment apparatus of the comparative example is different from the substrate treatment apparatus of FIG. 6 in that the third AC power supply 42 and the filter circuit 60 are omitted and the inductor and capacitor are changed so that the filter circuit 61 has high impedance against AC power supply with the first frequency. For a configuration example for blocking the frequency of 60 MHz, a configuration in which the capacitor 61a is set to 703.62 pF and the inductor 61b is set to 10 nH can be considered. Although impedance of the apparatus with the first frequency of 60 MHz in the comparative example is high impedance of 4 MΩ, the impedance is 112 Ω for the frequency of 59 MHz, and the impedance is 114 Ω for the frequency of 61 MHz. In the case of the comparative example, the impedance becomes low even if the frequency is slightly changed. Therefore, in the case of the substrate processing apparatus of the comparative example, for example, when the frequency is changed from 59 MHz to 61 MHz for frequency matching, the range of the blocking frequency becomes narrow.

The substrate treatment apparatus according to the present embodiment has been described in detail above. Further, the technical scope of the present disclosure is not limited to the above-described embodiments and can be variously modified within the scope not departing from the gist of the present disclosure. In addition, constituent elements of the embodiments can be appropriately replaced with known constituent elements and the above-described embodiments can be appropriately combined within a scope not departing from the gist of the present disclosure.

### BRIEF DESCRIPTION OF THE REFERENCE SYMBOLS

### 12 Chamber

14 Lower electrode
16 Upper electrode
29 First AC power supply
36 Filter circuit

What is claimed is:

1. A substrate treatment apparatus comprising:
a lower electrode formed of a dielectric;
a first AC power supply that is connected to a first internal electrode included in the lower electrode and supplies AC power with a first frequency;
a heater included in the lower electrode to heat the lower electrode;
a filter circuit connected to the heater; and
a second AC power supply connected to the heater via the filter circuit and used for the heater,
wherein the filter circuit includes a parallel circuit that connects a low-pass filter with a cut-off frequency that is lower than the first frequency and a high-pass filter with a cut-off frequency that is higher than the first frequency in parallel.

2. The substrate treatment apparatus according to claim 1, wherein the filter circuit includes a second low-pass filter with a cut-off frequency that is lower than the first frequency between the heater and the parallel circuit.

3. The substrate treatment apparatus according to claim 1, wherein the first frequency is 60 MHz.

4. The substrate treatment apparatus according to claim 2, comprising:
a third AC power supply that supplies AC power with a second frequency that is lower than the first frequency; and
a second filter circuit that attenuates the AC power with the second frequency.

5. The substrate treatment apparatus according to claim 4, wherein the second frequency is 430 kHz.

6. The substrate treatment apparatus according to claim 1, comprising:
a second internal electrode included in the lower electrode;
a third filter circuit connected to the second internal electrode; and
a DC power supply connected to the second internal electrode via the third filter circuit and used for an electrostatic chuck.
